(19) United States
(12) Patent Application Publication
(10) Pub. No.: US 2026/0020472 A1
(43) Pub. Date: Jan. 15, 2026

(54) DISPLAY DEVICE

(71) Applicant: Japan Display Inc., Tokyo (JP)

(72) Inventors: Hiroshi TABATAKE, Tokyo (JP); Masato NAKAMURA, Tokyo (JP)

(73) Assignee: Japan Display Inc., Tokyo (JP)

(21) Appl. No.: 19/263,571

(22) Filed: Jul. 9, 2025

(30) Foreign Application Priority Data
Jul. 10, 2024 (JP) 2024-111120

(51) Int. Cl. H10K 59/80; H10K 59/40

(52) U.S. Cl. CPC H10K 59/80515; H10K 59/40

(57) ABSTRACT

According to one embodiment, a display devices includes, a first lower electrode, a second lower electrode, and a third lower electrode that are arranged in order in a first direction in a display area, organic layers respectively provided on the first lower electrode, the second lower electrode, and the third lower electrode and each including a light emitting layer, an upper electrode provided on the organic layer, and a detection electrode for detecting contact or approach of an object to the display area. The detection electrode extends in a second direction, includes a first segment located between the first lower electrode and the second lower electrode in plan view, and does not include a segment between the second lower electrode and the third lower electrode.

### CROSS-REFERENCE TO RELATED APPLICATION

This application is based upon and claims the benefit of priority from Japanese Patent Application No. 2024-111120, filed Jul. 10, 2024, the entire contents of which are incorporated herein by reference.

### FIELD

Embodiments described herein relate generally to a display device.

### BACKGROUND

Recently, display devices to which an organic light emitting diode (OLED) is applied as a display element and which comprise touch sensor function for detecting contact or approach of an object to a display area have been put into practical use. In this type of display devices, an optical device such as an illumination sensor and a camera are assumed to be provided in a rear side of a display element. In that case, the display devices require that an area transmitting light be provided in a display area.

### BRIEF DESCRIPTION OF THE DRAWINGS

FIG. 1 is a view showing a configuration example of a display device DSP.

FIG. 2 is a schematic plan view showing elements for implementing the touch sensor function.

FIG. 3 is a plan view schematically showing a configuration example of the layout of pixels PX and the layout of a detection electrode DT in a display area DA.

FIG. 4 is a schematic cross-sectional view showing the display device DSP along the A-B line of FIG. 3.

FIG. 5 is a schematic cross-sectional view of the display device DSP along the C-D line of FIG. 3.

FIG. 6 is a plan view schematically showing another configuration example of the layout of the pixels PX and the layout of the detection electrode DT in the display area DA.

FIG. 7 is a plan view schematically showing another configuration example of the layout of the pixels PX and the layout of the detection electrode DT in the display area DA.

FIG. 8 is a plan view schematically showing another configuration example of the layout of the pixels PX and the layout of the detection electrode DT in the display area DA.

FIG. 9 is a schematic cross-sectional view of the display device DSP along the E-F line of FIG. 8.

FIG. 10 is a schematic cross-sectional view of the display device DSP along the G-H line of FIG. 8.

### DETAILED DESCRIPTION

Embodiments described herein aim to provide a display device that comprises a touch sensor function and is configured to allow an external device to achieve desired performance.

In general, according to one embodiment, a display devices includes, in a display area for displaying an image, a first lower electrode, a second lower electrode, and a third lower electrode that are arranged in order in a first direction, organic layers respectively provided on the first lower electrode, the second lower electrode, and the third lower electrode and each including a light emitting layer, an upper electrode provided on the organic layer, and a detection electrode for detecting contact or approach of an object to the display area. The detection electrode extends in a second direction intersecting the first direction, includes a first segment located between the first lower electrode and the second lower electrode in plan view, and does not include a segment between the second lower electrode and the third lower electrode.

According to another embodiment, a display device includes a plurality of pixels provided in a display area for displaying an image and a detection electrode for detecting contact or approach of an object to the display area. Each of the plurality of pixels includes a first subpixel and a second subpixel adjacent thereto. The detection electrode includes a plurality of segments each surrounding the plurality of pixels in plan view and does not include a segment between the first subpixel and the second subpixel.

Embodiments described herein can provide a display device that comprises a touch sensor function and is configured to allow an external device to achieve desired performance.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis, and a Z-axis orthogonal to each other are described to facilitate understanding as needed. A direction parallel to the X-axis is referred to as a first direction X. A direction parallel to the Y-axis is referred to as a second direction Y. A direction parallel to the Z-axis is referred to as a third direction Z. A plan view is defined as appearance when various types of elements are viewed parallel to the third direction Z. When terms indicating the positional relationships of two or more structural elements, such as “on”, “above” “between” and “face”, are used, the target structural elements may be directly in contact with each other or may be spaced apart from each other as a gap or another structural element is interposed between them. The positive direction of the Z-axis is referred to as an upward direction or a direction to an upper side.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone, and a wearable terminal.

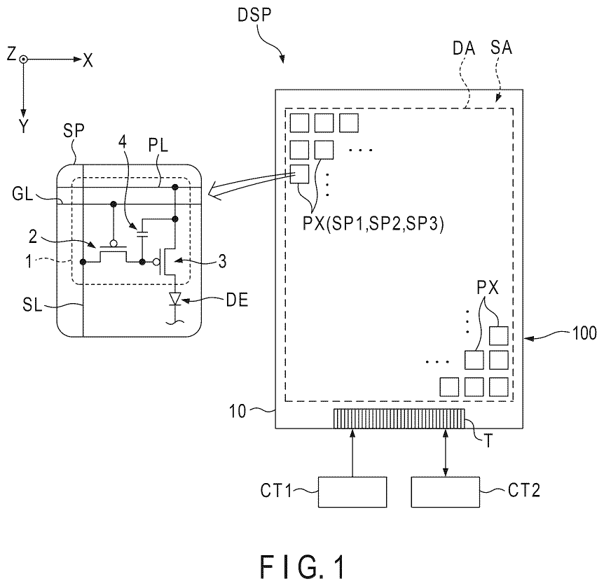

FIG. 1 is a view showing a configuration example of a display device DSP.

The display device DSP comprises a display panel 100. The display panel 100 has a display area DA for displaying an image and a surrounding area SA around the display area DA on an insulating substrate 10. The substrate 10 may be either a glass substrate or a resinous substrate having flexibility.

In the illustrated example, the shape of the substrate 10 is a rectangle in plan view. The shape of the substrate 10 in plan view is not limited to a rectangle and may be another shape such as a square, a circle or an oval.

The display area DA comprises a plurality of pixels PX arrayed in a matrix in the first direction X and the second direction Y. Each pixel PX includes a plurality of subpixels SP that display different colors. For example, each pixel PX includes a subpixel SP1 which displays the first color, a subpixel SP2 which displays the second color, and a subpixel SP3 which displays the third color. The first color, the second color, and the third color are different colors. Each pixel PX may include a subpixel SP, which displays another color such as white in addition to the subpixels SP1, SP2, and SP3 or instead of one of the subpixels SP1, SP2, and SP3.

The subpixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

A gate electrode of the pixel switch 2 is connected to a scanning line GL. One of a source electrode and a drain electrode of the pixel switch 2 is connected to a signal line SL. The other is connected to a gate electrode of the drive transistor 3 and the capacitor 4. In the drive transistor 3, one of a source electrode and a drain electrode is connected to a power line PL and the capacitor 4. The other is connected to a display element DE.

The configuration of the pixel circuit 1 is not limited to the illustrated example. For example, the pixel circuit 1 may comprise more thin-film transistors and capacitors.

For example, the display element DE is an organic light emitting diode (OLED) as a light emitting element and thus may be called an organic EL element.

The display device DSP further comprises a terminal portion T provided in the surrounding area SA. The terminal portion T comprises a plurality of terminals. For example, the terminal portion T is electrically connected to an IC chip or a flexible printed circuit board for driving the display device DSP.

The display device DSP further comprises a display controller CT1 for controlling the image display of the display area DA and a detection controller CT2 for implementing the touch sensor function of detecting contact or approach of an object to the display area DA. Each of the display controller CT1 and the detection controller CT2 is mounted, for example, on the flexible printed circuit board described above. As another example, the display controller CT1 and the detection controller CT2 may be mounted in the surrounding area SA.

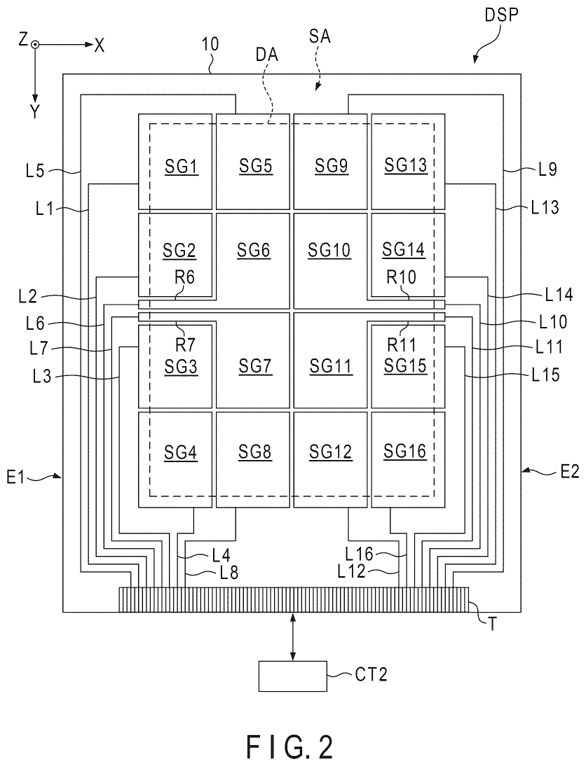

FIG. 2 is a schematic plan view showing elements for implementing the touch sensor function.

The display device DSP comprises a plurality of sensor modules SG, which function as electrodes for the touch sensor. These sensor modules SG are constituted by a detection electrode to be described later.

In the illustrated example, 16 sensor modules SG (SG1 to SG16) overlapping the display area DA are arranged in a matrix consisting of 4 columns×4 rows. The number and the layout of the sensor modules SG are not limited to this example.

The sensor modules SG1 to SG16 are electrically connected to the terminal portion T via respective leads L1 to L16 provided in the surrounding area SA. In the illustrated example, the leads L1 to L3 and L5 to L7 are provided between the display area DA and an end portion E1 of the substrate 10 in the left side of the figure and extend to the terminal portion T. Further, the leads L9 to L11 and L13 to L15 are provided between the display area DA and an end portion E2 of the substrate 10 in the right side of the figure and extend to the terminal portion T. The leads L4, L8, L12, and L16 are provided between the display area DA and the terminal portion T.

The sensor modules SG6, SG7, SG10, and SG11 are surrounded by the other sensor modules SG. In the illustrated example, relay portions R6, R7, R10, and R11 are provided in the display area DA to enable the respective connections between these sensor modules SG6, SG7, SG10, and SG11 and the leads L6, L7, L10, and L11.

The relay portions R6, R7, R10, and R11 electrically connect the sensor modules SG6, SG7, SG10, and SG11 to the leads L6, L7, L10, and L11, respectively. The relay portions R6 and R7 are located between the sensor modules SG2 and SG3. The relay portions R10 and R11 are located between the sensor modules SG14 and SG15.

The detection controller CT2 supplies each of the sensor modules SG1 to SG16 with drive signals through the leads L1 to L16 with a predetermined period. These drive signals charge the capacity of the sensor modules SG1 to SG16 themselves.

After the supply of the drive signal, the detection controller CT2 reads detection signals (output voltage) from the sensor modules SG1 to SG16 through the leads L1 to L16. The detection signal corresponds to, for example, the amount of charge stored in the capacity of the sensor modules SG1 to SG16 themselves.

Among the sensor modules SG1 to SG16 arrayed in an X-Y plane (a detection surface), the value of the detection signal differs between the sensor modules SG that are close to an object such as a finger of the user and the other sensor modules SG. Thus, the detection controller CT2 can detect location information of the object based on the detection signal of each of the sensor modules SG.

When the display device DSP operates, a display period for image display and a sensor period for touch detection are alternately repeated. In each display period, display voltage is written to each of the display elements DE. In each sensor period, supply of drive signals to the sensor modules SG1 to SG16 and reading of drive signals from the sensor modules SG1 to SG16 are performed. The display voltage written in the display period is maintained in the sensor period as well.

The detection system using the sensor modules SG1 to SG16 and the operation of the display device DSP are not limited to the example shown here.

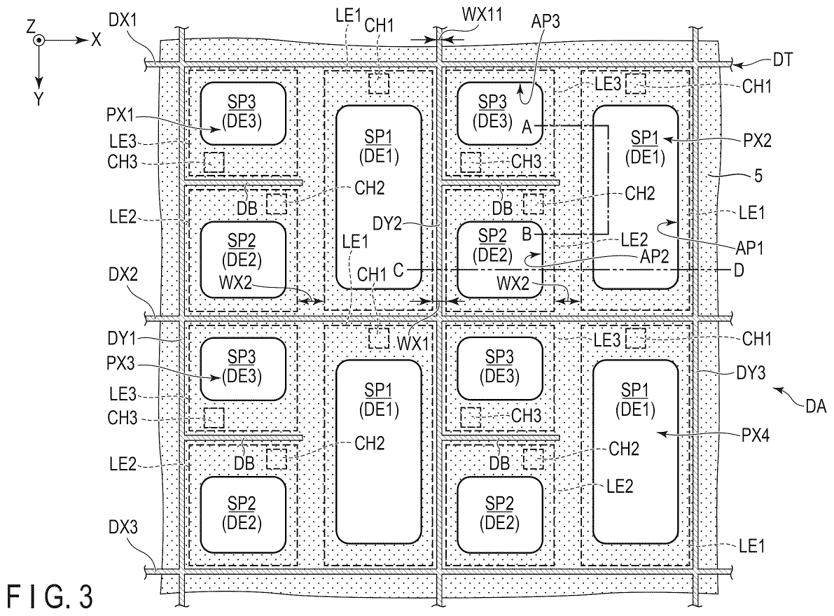

FIG. 3 is a plan view schematically showing a configuration example of the layout of the pixels PX and the layout of the detection electrode DT in the display area DA.

The following description focuses on four pixels: pixels PX1, PX2, PX3, and PX4 arrayed in a matrix in the first direction X and the second direction Y in the display area DA.

The pixels PX1 and PX2 are arranged in the first direction X. The pixels PX3 and PX4 are arranged in the first direction X. The pixels PX1 and PX3 are arranged in the second direction Y. The pixels PX2 and PX4 are arranged in the second direction Y.

Each of the pixels PX1, PX2, PX3, and PX4 includes the subpixels SP1, SP2, and SP3. In the illustrated example, the subpixels SP2 and SP3 are arranged in the second direction Y. The subpixels SP2 and SP1 are arranged in the first direction X. The subpixels SP3 and SP1 are arranged in the first direction X.

When the subpixels SP1, SP2, and SP3 are arranged in this layout, in the display area DA, a column in which the subpixels SP2 and SP3 are alternately arranged in the second direction Y and a column in which a plurality of the subpixels SP1 are arranged in the second direction Y are formed. These columns are alternately arranged in the first direction X. The layout of the subpixels SP1, SP2, and SP3 is not limited to the illustrated example.

An insulating layer 5 is provided in the display area DA. The insulating layer 5 has apertures AP1, AP2, and AP3 in the subpixels SP1, SP2, and SP3, respectively. The insulating layer 5 having these apertures AP1, AP2, and AP3 may be called a rib. In the illustrated example, the planer size of the aperture AP1, the planar size of the aperture AP2, and the planar size of the aperture AP3 differ from one another. The planer size of the aperture AP1 is greater than that of the aperture AP2. The planer size of the aperture AP2 is greater than that of the aperture AP3.

The subpixels SP1, SP2, and SP3 comprise display elements DE1, DE2, and DE3, respectively, as the display elements DE. The display element DE comprises a lower electrode, an upper electrode facing the lower electrode, and an organic layer located between the lower electrode and the upper electrode. FIG. 3 shows the lower electrode but omits the illustration of the upper electrode and the organic layer. For example, the lower electrode corresponds to the anode of the display element DE, and the upper electrode corresponds to the cathode of the display element DE.

The display element DE1 comprises a lower electrode LE1 overlapping the aperture AP1. The peripheral portion of the lower electrode LE1 overlaps the insulating layer 5 in plan view. The lower electrode LE1 is electrically connected to the drive transistor 3 shown in FIG. 1 through a contact hole CH1.

The display element DE2 comprises a lower electrode LE2 overlapping the aperture AP2. The peripheral portion of the lower electrode LE2 overlaps the insulating layer 5 in plan view. The lower electrode LE2 is electrically connected to the drive transistor 3 shown in FIG. 1 through a contact hole CH2.

The display element DE3 comprises a lower electrode LE3 overlapping the aperture AP3. The peripheral portion of the lower electrode LE3 overlaps the insulating layer 5 in plan view. The lower electrode LE3 is electrically connected to the drive transistor 3 shown in FIG. 1 through a contact hole CH3.

The detection electrode DT constitutes the sensor modules shown in FIG. 2 and is formed into a grating shape surrounding each of the pixels PX1, PX2, PX3, and PX4 in plan view. That is, the detection electrode DT includes a plurality of segments DX1, DX2, and DX3 extending in the first direction X and a plurality of segments DY1, DY2, and DY3 extending in the second direction Y. The segments DX1, DX2, and DX3 are arranged in this order in the second direction Y and adjacent to each other. The segments DY1, DY2, and DY3 are arranged in this order in the first direction X and adjacent to each other. The segments DX1, DX2, and DX3 and the segments DY1, DY2, and DY3 are connected to each other.

As described above, the touch sensor function is implemented by detecting a capacity variation in the sensor modules constituted by the detection electrode DT. Thus, the detection electrode DT is preferably formed across as wide an area as possible for ensuring the capacity of the detection electrode DT.

This detection electrode DT does not have a segment between the subpixels SP1 and SP2 and between the subpixels SP1 and SP3 in each of the pixels PX1, PX2, PX3, and PX4.

From another viewpoint, the detection electrode DT does not have a segment between the lower electrodes LE1 and LE2 and between the lower electrodes LE1 and LE3 in plan view in each of the pixels PX1, PX2, PX3, and PX4.

The segment DY2 is located between the subpixel SP1 of the pixel PX1 and the subpixel SP2 of the pixel PX2 and between the subpixel SP1 of the pixel PX1 and the subpixel SP3 of the pixel PX2. The segment DY2 is located between the subpixel SP1 of the pixel PX3 and the subpixel SP2 of the pixel PX4 and between the subpixel SP1 of the pixel PX3 and the subpixel SP3 of the pixels PX4.

From another view point, the segment DY2 is located between the lower electrode LE1 of the pixel PX1 and the lower electrode LE2 of the pixel PX2 and between the lower electrode LE1 of the pixel PX1 and the lower electrode LE3 of the pixel PX2 in plan view. The segment DY2 is located between the lower electrode LE1 of the pixel PX3 and the lower electrode LE2 of the pixel PX4 and between the lower electrode LE1 of the pixel PX3 and the lower electrode LE3 of the pixel PX4.

The detection electrode DT further includes a branched segment DB. The branched segment DB is located between the subpixels SP2 and SP3 or between the lower electrodes LE2 and LE3 and extend in the first direction X in each of the pixels PX1, PX2, PX3, and PX4 in plan view. One end of the branched segment DB is connected to the segment DY extending in the second direction Y. The other end of the branched segment DB is not connected to any of the segments and does not overlap the subpixel SP1 or the lower electrode LE1 in plan view.

For example, the pixel PX2 is surrounded by the segments DX1 and DX2 and the segments DY2 and DY3. That is, the subpixel SP1 or the lower electrode LE1, the subpixel SP2 or the lower electrode LE2, and the subpixel SP3 or the lower electrode LE3 are located between the segments DY2 and DY3 in the first direction X. Further, the subpixel SP1 or the lower electrode LE1, the subpixel SP2 or the lower electrode LE2, and the subpixel SP3 or the lower electrode LE3 are located between the segments DX1 and DX2 in the second direction Y.

Further, the subpixel SP1 or the lower electrode LE1 is surrounded by the segments DX1, DX2, and DY3 in the pixel PX2. Further, the subpixel SP2 or the lower electrode LE2 is surrounded by the branched segment DB and the segments DX2 and DY2. Further, the subpixel SP3 or the lower electrode LE3 is surrounded by the segment DX1, the branched segment DB, and the segment DY2. That is, three sides of each of the subpixels SP1, SP2, and SP3 and lower electrodes LE1, LE2, and LE3 is surrounded by three segments of the detection electrode DT.

An interval WX1 along the first direction X between the lower electrode LE1 of the pixel PX1 and the lower electrode LE2 of the pixel PX2 is smaller than an interval WX2 along the first direction X between the lower electrode LE1 of the pixel PX2 and the lower electrode LE2 of the pixel PX2 (WX1<WX2). That is, among the plurality of segments constituting the detection electrode DT, the segment DY extending in the second direction Y is provided to overlap an area with a relatively narrow width between the pixels PX adjacent to each other in the first direction X. On the other hand, the segment DY is not provided in an area with a relatively broad width in each of the pixels PX.

A width WX11 along the first direction X of the segment DY extending in the second direction Y is smaller than the interval WX1 (WX11<WX1). Thus, for example, the segment DY2 does not entirely overlap the area between the lower electrodes LE1 and LE2 in plan view.

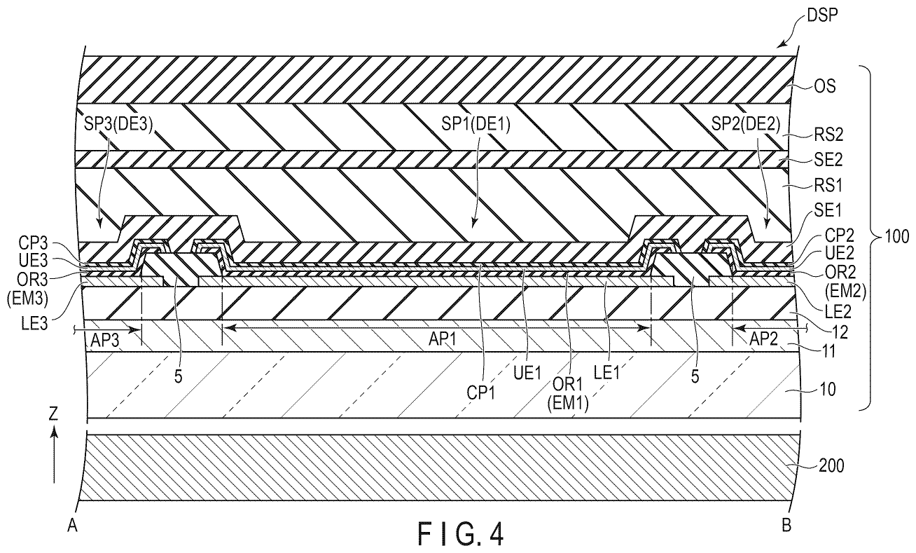

FIG. 4 is a schematic cross-sectional view showing the display device DSP along the A-B line of FIG. 3.

A circuit layer 11 is provided on the substrate 10. The circuit layer 11 includes various circuits such as the pixel circuits 1 shown in FIG. 1, various lines such as the scanning lines GL, the signal lines SL, and the power lines PL, and various insulating layers.

An insulating layer 12 is provided on the circuit layer 11. For example, the insulating layer 12 is an organic insulating layer that planarizes the uneven parts formed by the circuit layer 11.

The lower electrode LE1 of the subpixel SP1, the lower electrode LE2 of the subpixel SP2, and the lower electrode LE3 of the subpixel SP3 are provided on the insulating layer 12 and are spaced apart from one another.

The insulating layer 5 is an inorganic insulating layer or an organic insulating layer and is provided on the insulating layer 12 and the lower electrodes LE1, LE2, and LE3. The aperture AP1 of the insulating layer 5 overlaps the lower electrode LE1. The aperture AP2 overlaps the lower electrode LE2. The aperture AP3 overlaps the lower electrode LE3. The peripheral portions of the lower electrodes LE1, LE2, and LE3 are covered with the insulating layer 5. The contact holes CH1, CH2, and CH3 shown in FIG. 3 are formed on the insulating layer 12, but illustration of them is omitted here.

The organic layer OR1 contacts the lower electrode LE1 through the aperture AP1 and covers the lower electrode LE1 exposed from the aperture AP1. The peripheral portion of the organic layer OR1 is located on the insulating layer 5. The upper electrode UE1 covers the organic layer OR1.

The organic layer OR2 contacts the lower electrode LE2 through the aperture AP2 and covers the lower electrode LE2 exposed from the aperture AP2. The peripheral portion of the organic layer OR2 is located on the insulating layer 5. The upper electrode UE2 covers the organic layer OR2.

The organic layer OR3 contacts the lower electrode LE3 through the aperture AP3 and covers the lower electrode LE3 exposed from the aperture AP3. The peripheral portion of the organic layer OR3 is located on the insulating layer 5. The upper electrode UE3 covers the organic layer OR3.

In the illustrated example, the subpixel SP1 has a cap layer CP1, the subpixel SP2 has a cap layer CP2, and the subpixel SP3 has a cap layer CP3. The cap layers CP1, CP2, and CP3 function as optical adjustment layers, which improve the extraction efficiency of light emitted from the organic layers OR1, OR2, and OR3, respectively. The cap layer CP1 is provided on the upper electrode UE1. The cap layer CP2 is provided on the upper electrode UE2. The cap layer CP3 is provided on the upper electrode UE3. The cap layers CP1, CP2, and CP3 may be omitted.

The sealing layer SE1 is provided to cover the cap layers CP1, CP2, and CP3 and the insulating layer 5.

A transparent resin layer RS1 covers the sealing layer SE1. The sealing layer SE2 covers the resin layer RS1. A transparent resin layer RS2 covers the sealing layer SE2. An optical sheet OS is, for example, a polarizer and is bonded to the resin layer RS2.

Each of the sealing layers SE1 and SE2 is formed of an inorganic insulating material such as a silicon nitride (SiNx), a silicon oxide (SiOx), a silicon oxynitride (SiON), or an aluminum oxide (Al₂O₃).

Each of the lower electrodes LE1, LE2, and LE3 is, for example, a multilayer body having a transparent layer formed of an oxide conductive material such as indium tin oxide (ITO) and a reflective layer formed of a metal material such as silver. For example, each of the lower electrodes LE1, LE2, and LE3 is a multilayer body having a reflective layer between a pair of transparent layers.

The organic layer OR1 has a light emitting layer EM1. The organic layer OR2 has a light emitting layer EM2. The organic layer OR3 has a light emitting layer EM3. The light emitting layers EM1, EM2, EM3 are formed of materials different from one another. For example, the light emitting layer EM1 is formed of a material that emits light in a blue wavelength range. The light emitting layer EM2 is formed of a material that emits light in a green wavelength range. The light emitting layer EM3 is formed of a material that emits light in a red wavelength range.

Each of the organic layers OR1, OR2, and OR3 has a plurality of functional layers such as a hole injection layer, a hole transport layer, an electron blocking layer, a hole blocking layer, an electron transport layer, and an electron injection layer.

Each of the upper electrodes UE1, UE2, and UE3 is formed of, for example, a metal material such as an alloy of magnesium and silver (MgAg).

Each of the cap layers CP1, CP2, and CP3 is a multilayer body consisting of a plurality of thin films. All of the thin films are transparent and have refractive indices different from one another.

An external device 200 faces the display panel 100 and is provided on the rear side of the display panel 100 in the third direction Z. The external device 200 is, for example, an optical device configured to receive light passing through the display panel 100 and output electric signals. The external device 200 may comprise an illumination sensor or a camera. Alternatively, the external device 200 may be a communication device configured to transmit or receive radio waves via the display panel 100.

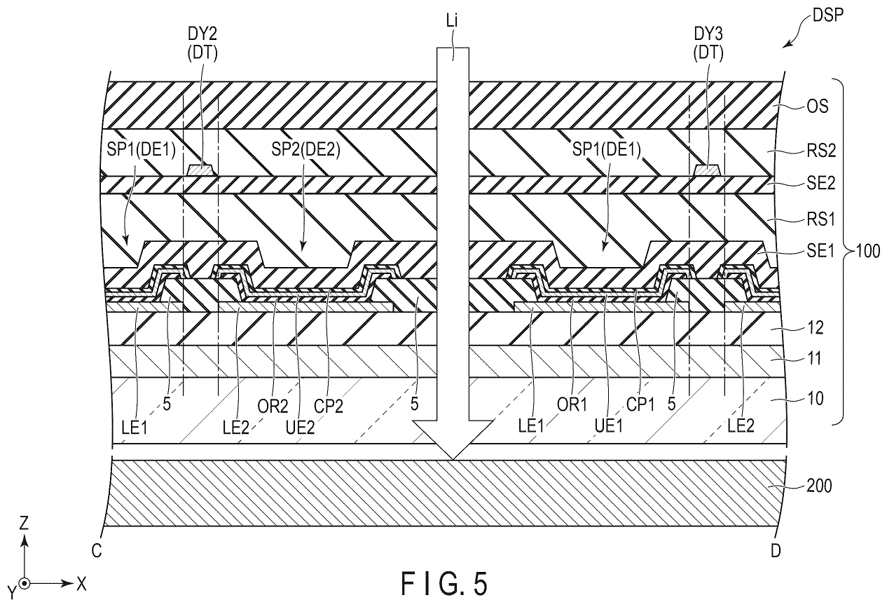

FIG. 5 is a schematic cross-sectional view of the display device DSP along the C-D line of FIG. 3.

The detection electrode DT including the segments DY2 and DY3 is provided on the sealing layer SE2 and is covered with the resin layer RS2. For example, the detection electrode DT is a multilayer body having an aluminum layer formed of an aluminum-based material and a titanium layer formed of a titanium-based material.

For example, in the subpixels SP1 and SP2 located at the center of the figures, the detection electrode DT is not provided in an area between the lower electrodes LE1 and LE2. Thus, a transmissive area transmitting light Li can be formed between the lower electrodes LE1 and LE2. In cases where the external device 200 is the optical device, the external device 200 can receive the light Li having passed through the transmissive area. Further, even when the segment DY extending in the second direction Y is shifted in the first direction X at the time of forming the detection electrode DT, the transmissive area does not overlap the segment DY. Thus, the light Li can be reliably received by the external device 200.

Further, in the subpixels SP1 and SP2 in the left side of the figure, the segment DY2 is provided to overlap the area between the lower electrodes LE1 and LE2. Similarly, in the subpixels SP1 and SP2 in the right side of the figure, the segment DY3 is provided to overlap the area between the lower electrodes LE1 and LE2. As described above, the width of the segment DY extending in the second direction Y is smaller than the interval between the lower electrodes LE1 and LE2. Thus, the segment DY does not completely close the area between the lower electrodes LE1 and LE2. Thus, the area transmitting light Li can be formed. Thus, the external device 200 can receive the light Li in the area in which the segment DY is provided as well.

Thus, the external device 200 can achieve desired performance.

For example, in cases where the external device 200 is an illumination sensor, the illumination sensor measures the luminance of the light Li made incident through the display device DSP (in other words, external light). A function of automatically adjusting the brightness of the display device DSP according to luminance measured by the illumination sensor can be implemented. For example, the function sets the brightness of the display device DSP higher in a brighter environment and sets the brightness of the display device DSP lower in a darker environment.

The above describes the cases where the external device 200 is the optical device. Even in cases where the external device 200 is the communication device, the transmissive area is formed as an area allowing radio waves to pass. Thus, the external device 200 can reliably transmit or receive radio waves, achieving desired performance.

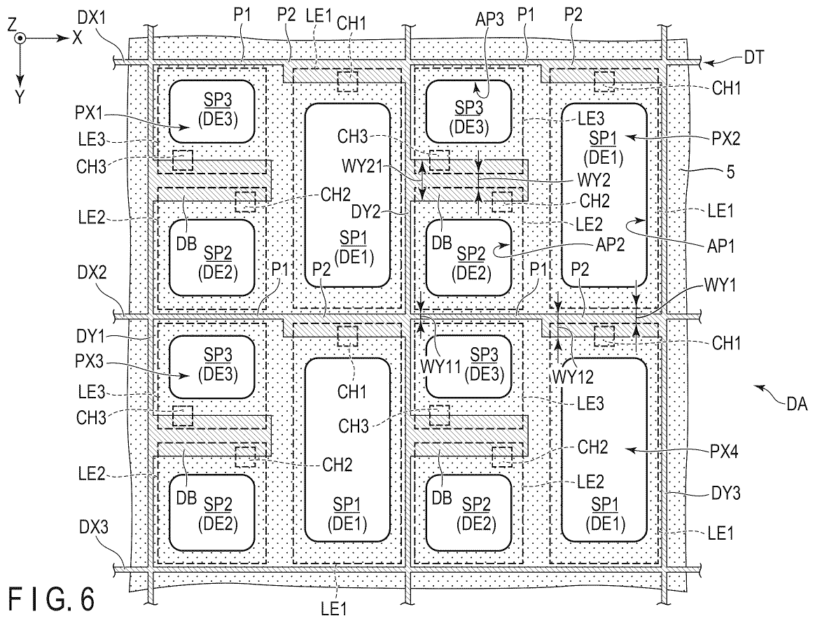

FIG. 6 is a plan view schematically showing another configuration example of the layout of the pixels PX and the layout of the detection electrode DT in the display area DA.

The configuration example shown in FIG. 6 differs from the configuration example shown in FIG. 3 in that a width WY21 along the second direction Y of the branched segment DB is greater than an interval WY2 along the second direction Y between the lower electrodes LE2 and LE3 (WY21>WY2). In the illustrated example, the width WY21 of the branched segment DB is constant in the first direction X. The branched segment DB overlaps the lower electrodes LE2 and LE3 and the contact holes CH2 and CH3 in plan view. However, the branched segment DB does not overlap the apertures AP2 and AP3.

The configuration example shown in FIG. 6 differs from the configuration example shown in FIG. 3 in that the segments DX extending in the first direction X is locally wide. In the illustrated example, each of the segments DX1 and DX2 has a first portion P1 having a first width WY11 along the second direction Y and a second portion P2 having a second width WY12 along the second direction Y. The second width WY12 is greater than the first width WY11 (WY12>WY11). An interval WY1 along the second direction Y between the lower electrode LE1 of the pixel PX2 and the lower electrode LE1 of the pixel PX4 is greater than the first width WY11 and is smaller than the second width WY12 (WY11<WY1<WY12).

The first portion P1 of the segment DX1, which is illustrated, is adjacent to the lower electrode LE3 of the pixel PX2 in the second direction Y. The first portion P1 of the segment DX2 is adjacent to the lower electrode LE2 of the pixel PX2 and the lower electrode LE3 of the pixel PX4 and is located between these lower electrodes LE2 and LE3 in the second direction Y.

The second portion P2 of each of the segments DX1 and DX2 is adjacent to the lower electrode LE1 in the second direction Y. Part of the second portion P2 overlaps at least part of the contact hole CH1 in plan view. Further, part of the second portion P2 of the segment DX1 overlaps part of the lower electrode LE1 of the pixel PX1. Part of the second portion P2 of the segment DX2 overlaps part of the lower electrode LE1 of the pixel PX4. In contrast, the segments DX1 and DX2 do not overlap the aperture AP1.

The positions of the contact holes CH1, CH2, and CH3 do not overlap the apertures AP1, AP2, and AP3. In an area where the contact hole CH is located between the segment DX extending in the first direction X, the branched segment DB, and the aperture AP, the segment DX and the branched segment DB are sufficiently farther from the aperture AP. Thus, even if the segment DX and the branched segment DB are shifted in the second direction Y at the time of forming the detection electrode DT, the segment DX and the branched segment DB do not overlap the aperture AP.

On the other hand, the expansion of the second portions P2 of the branched segment DB and the segment DX can increase the installation area of the detection electrode DT and the capacity of the detection electrode DT. Thus, the detection sensitivity of the detection electrode DT can be improved.

In addition, as in the configuration example, in each of the pixels PX1, PX2, PX3, and PX4, a transmissive area that does not overlap the segments of the detection electrode DT is formed between the lower electrodes LE1 and LE2 and between the lower electrodes LE1 and LE3. Thus, the effects similar to those of the above configuration example can be achieved.

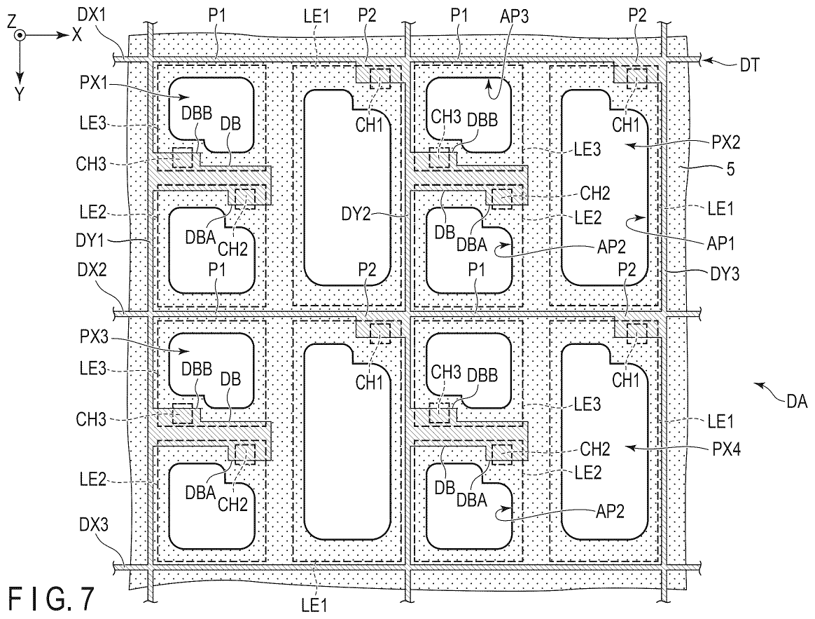

FIG. 7 is a plan view schematically showing another configuration example of the layout of the pixels PX and the layout of the detection electrode DT in the display area DA.

The configuration example shown in FIG. 7 differs from the configuration example shown in FIG. 3 in that the branched segment DB has a first protrusion portion DBA protruding toward the lower electrode LE2 and a second protrusion portion DBB protruding toward the lower electrode LE3. In the illustrated example, part of the first protrusion portion DBA overlaps at least part of the contact hole CH2, and part of the second protrusion portion DBB overlaps at least part of the contact hole CH3. However, the first protrusion portion DBA does not overlap the aperture AP2, and the second protrusion portion DBB does not overlap the aperture AP3.

In addition, as in the configuration example shown in FIG. 6, the segment DX extending in the first direction X is locally wide and has the first portion P1 and the second portion P2.

This configuration example achieves the same

effects as those of the configuration example described with reference to FIG. 6.

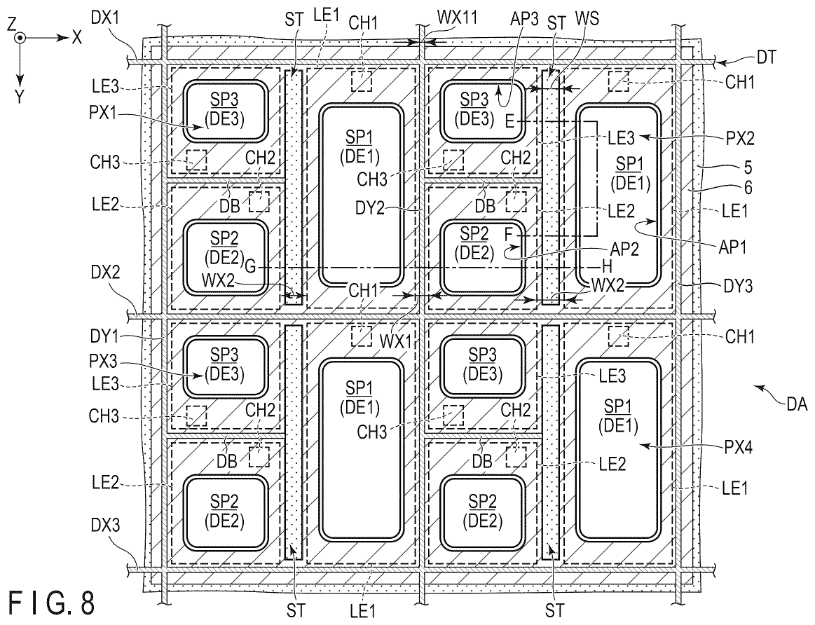

FIG. 8 is a plan view schematically showing another configuration example of the layout of the pixels PX and the layout of the detection electrode DT in the display area DA.

The configuration example shown in FIG. 8 differs from the configuration example shown in FIG. 3 in that a partition 6 is provided.

The partition 6 entirely overlaps the insulating layer 5 and has a planar shape similar to that of the insulating layer 5. In other words, the partition 6 has an aperture in each of the subpixels SP1, SP2, and SP3. From another viewpoint, each of the insulating layer 5 and the partition 6 has a lattice shape in plan view and surrounds each of the display elements DE1, DE2, and DE3, or each of the lower electrodes LE1, LE2, and LE3. The partition 6 is formed of a conductive material and serves as a wire for supplying the upper electrodes of each of the display elements DE1, DE2, and DE3 with a common voltage.

The segments DX1, DX2, and DX3, the segments DY1, DY2, and DY3, and the branched segment DB of the detection electrode DT all overlap the partition 6 in plan view.

In addition, the partition 6 has a slit ST, which does not overlap the detection electrode DT in plan view. In the illustrated example, the slits ST are located between the lower electrodes LE1 and LE2 and between the lower electrodes LE1 and LE3 in each of the pixels PX1, PX2, PX3, and PX4 and extend in the second direction Y. The slit ST does not overlap any of the segments DX1, DX2, and DX3, the segments DY1, DY2, and DY3, and the branched segment DB. This slit ST exposes the insulating layer 5.

A width WS along the first direction X of the slit ST is smaller than the interval WX2 along the first direction X between the lower electrodes LE1 and LE2 (WS<WX2).

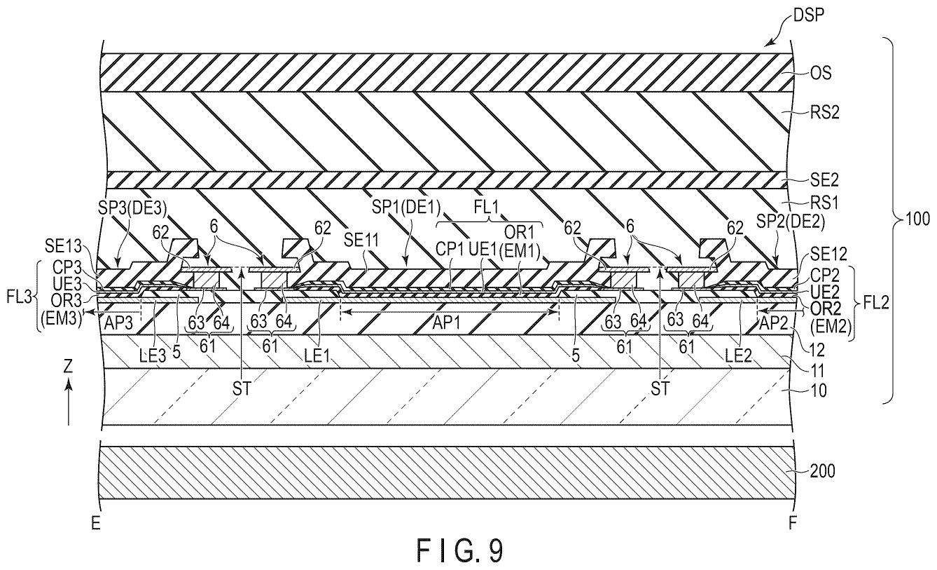

FIG. 9 is a schematic cross-sectional view of the display device DSP along the E-F line of FIG. 8. In the following, explanations that overlap those provided with reference to FIG. 4 may be omitted.

The circuit layer 11 is provided on the substrate 10. The insulating layer 12 is provided on the circuit layer 11. The lower electrode LE1 of the subpixel SP1, the lower electrode LE2 of the subpixel SP2, and the lower electrode LE3 of the subpixel SP3 are provided on the insulating layer 12.

The insulating layer 5 is an inorganic insulating layer and covers the insulating layer 12 and the periphery portions of the lower electrodes LE1, LE2, and LE3. The aperture AP1 of the insulating layer overlaps the lower electrode LE1. The aperture AP2 overlaps the lower electrode LE2. The aperture AP3 overlaps the lower electrode LE3. The insulating layer 5 is formed of, for example, an inorganic insulating material such as a silicon nitride (SiNx) or a silicon oxynitride (SiON).

The partition 6 has a conductive lower portion 61 provided on the insulating layer 5 and an upper portion 62 provided on the lower portion 61.

In the illustrated example, the lower portion 61 has a bottom layer 63 provided on the insulating layer 5 and a stem layer 64 provided between the bottom layer 63 and the upper portion 62. The bottom layer 63 is thinner than the stem layer 64. The bottom layer 63 has the width greater than that of the stem layer 64. The both end portions of the bottom layer 63 protrude relative to the side surfaces of the stem layer 64.

The upper portion 62 is provided on the stem layer 64. The upper portion 62 has the width greater than that of the stem layer 64. The both end portions of the upper portion 62 protrude relative to the side surfaces of the stem layer 64. In the present specification, the side surfaces of the stem layer 64 are assumed to be the side surfaces of the stem layer 64 that extend between the bottom layer 63 and the upper portion 62. In the illustrated example, the upper portion 62 has the width greater than that of the bottom layer 63. The bottom layer 63 may have a width 30 greater than that of the upper portion 62.

The slit ST of the partition 6 corresponds to a portion that penetrates the bottom layer 63 and the stem layer 64 of the lower portion 61 and the upper portion 62.

In the display element DE1, the organic layer OR1 contacts the lower electrode LE1 through the aperture AP1 and covers the lower electrode LE1 exposed from the aperture AP1. The peripheral portion of the organic layer OR1 is located on the insulating layer 5. The upper electrode UE1 covers the organic layer OR1 and contacts the lower portion 61.

In the display element DE2, the organic layer OR2 contacts the lower electrode LE2 through the aperture AP2, covers the lower electrode LE2 exposed from the aperture AP2. The peripheral portion of the organic layer OR2 is located on the insulating layer 5. The upper electrode UE2 covers the organic layer OR2 and contacts the lower portion 61.

In the display element DE3, the organic layer OR3 contacts the lower electrode LE3 through the aperture AP3 and covers the lower electrode LE3 exposed from the aperture AP3. The peripheral portion of the organic layer OR3 is located on the insulating layer 5. The upper electrode UE3 covers the organic layer OR3 and contacts the lower portion 61.

The contact between each of the upper electrodes UE1, UE2, and UE3 and the lower portion 61 includes a case where each of the upper electrodes UE1, UE2, and UE3 directly contacts the upper surface of the bottom layer 63 and a case where each of the upper electrodes UE1, UE2, and UE3 directly contacts the upper surface of the bottom layer 63 and further directly contacts the side surfaces of the stem layer 64. In this specification, the upper surface of the bottom layer 63 is assumed to have, of the bottom layer 63, the surface that directly contacts the stem layer 64 and the surface that protrudes relative to the stem layer 64 and faces the upper portion 62.

In the illustrated example, the subpixel SP1 has the cap layer CP1 and a sealing layer SE11. The subpixel SP2 has the cap layer CP2 and a sealing layer SE12. The subpixel SP3 has the cap layer CP3 and a sealing layer SE13. The cap layers CP1, CP2, and CP3 may be omitted.

The cap layer CP1 is provided on the upper electrode UE1. The cap layer CP2 is provided on the upper electrode UE2. The cap layer CP3 is provided on the upper electrode UE3.

The sealing layer SE11 is provided on the cap layer CP1, contacts the partition 6, and continuously covers each member of the subpixel SP1. The sealing layer SE11 contacts the stem layer 64 and the upper portion 62 of the partition 6 that surrounds the display element DE1.

The sealing layer SE12 is provided on the cap layer CP2, contacts the partition 6, and continuously covers each member of the subpixel SP2. The sealing layer SE12 contacts the stem layer 64 and the upper portion 62 of the partition 6 that surrounds the display element DE2.

The sealing layer SE13 is provided on the cap layer CP3, contacts the partition 6, and continuously covers each member of the subpixel SP3. The sealing layer SE13 contacts the stem layer 64 and the upper portion 62 of the partition 6 that surrounds the display element DE3.

Each of the sealing layers SE11, SE12, and SE13 is formed of an inorganic insulating material such as a silicon nitride (SiNx), a silicon oxide (SiOx), a silicon oxynitride (SiON), or an aluminum oxide (Al₂O₃).

In the following explanation, a multilayer body including the organic layer OR1, the upper electrode UE1, and the cap layer CP1 is called a stacked film FL1. A multilayer body including the organic layer OR2, the upper electrode UE2, and the cap layer CP2 is called a stacked film FL2. A multilayer body including the organic layer OR3, the upper electrode UE3, and the cap layer CP3 is called a stacked film FL3.

The end portions of the sealing layers SE11, SE12, and SE13 are located above the partition 6. In the illustrated example, the sealing layer SE11 located on the partition 6 between the subpixels SP1 and SP2 is spaced apart from the sealing layer SE12 located on this partition 6. Further, the sealing layer SE11 located on the partition 6 between the subpixels SP1 and SP3 is spaced apart from the sealing layer SE13 located on this partition 6.

The stacked films FL1, FL2, and FL3 are not formed on the partition 6. Cavities are formed between the sealing layer SE11 and the partition 6, between the sealing layer SE12 and the partition 6, and between the sealing layer SE13 and the partition 6.

The transparent resin layer RS1 covers the partition 6 and the sealing layers SE11, SE12, and SE13. The resin layer RS1 is filled into the slit ST of the partition 6, covers the bottom layer 63, the stem layer 64, and the upper portion 62, and contacts the insulating layer 5. Further, the resin layer RS1 is filled into the cavity formed on the partition 6.

In the lower portion 61 of the partition 6, the bottom layer 63 is formed of, for example, a titanium-based material such as titanium or a titanium compound. The stem layer 64 is formed of a material different from those of the bottom layer 63 and the upper portion 62, and is formed of, for example, an aluminum-based material such as aluminum or an aluminum compound.

The upper portion 62 of the partition 6 is formed of, for example, a conductive material. However, the upper portion 62 may be formed of an insulating material. The upper portion 62 is formed of a material different from that of the lower portion 61. For example, the upper portion 62 is formed of a titanium-based material such as titanium or a titanium compound or an oxide conductive material such as indium tin oxide (ITO).

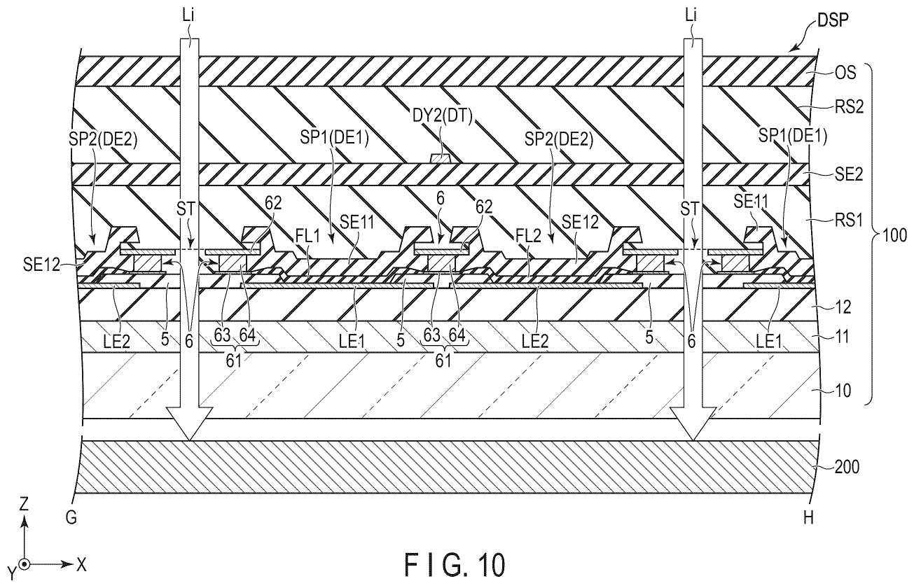

FIG. 10 is a schematic cross-sectional view of the display device DSP along the G-H line of FIG. 8.

The detection electrode DT including the segment DY2 is provided on the sealing layer SE2 and is covered with the resin layer RS2. For example, the detection electrode DT is a multilayer body having an aluminum layer formed of an aluminum-based material and a titanium layer formed of a titanium-based material.

For example, in the subpixels SP1 and SP2 in the left side of the figure, the detection electrode DT is not provided in an area between the lower electrodes LE1 and LE2 and an area overlapping the slit ST. Thus, a transmission area transmitting the light Li can be formed in the area that overlaps the slit ST of the areas between the lower electrodes LE1 and LE2.

Similarly, in the subpixels SP1 and SP2 in the right side of the figure, the transmission area transmitting the light Li can be formed in the area that overlaps the slit ST of the areas between the lower electrodes LE1 and LE2.

In cases where the external device 200 is the optical device, the external device 200 can receive the light Li having passed through the transmissive area. Further, even when the segment DY extending in the second direction Y is shifted in the first direction X at the time of forming the detection electrode DT, the transmissive area does not overlap the segment DY. Thus, the light Li can be reliably received by the external device 200.

Further, in the subpixels SP1 and SP2 at the center of the figure, the segment DY2 is provided to overlap the partition 6 between the lower electrodes LE1 and LE2. As described above, the partition 6 is formed of a metal material and forms a light-shielding area that does not transmit light. Similarly, the detection electrode DT is also formed of a metal material. Thus, the detection electrode DT does not transmit light, either. These partition 6 and detection electrode DT are provided to overlap each other in the third direction Z. Thus, the light-shielding area is not enlarged. Thus, the performance of the external device 200 is not affected.

Thus, the external device 200 can achieve desired performance.

Even in cases where the external device 200 is the communication device, the above transmissive area is formed as an area allowing radio waves to pass. Thus, the external device 200 can reliably transmit or receive radio waves, achieving desired performance.

In the embodiment, for example, the lower electrode LE1 of the pixel PX1 corresponds to the first lower electrode, the lower electrode LE2 of the pixel PX2 corresponds to the second lower electrode, the lower electrode LE1 of the pixel PX2 corresponds to the third lower electrode, and the lower electrode LE3 of the pixel PX2 corresponds to the fourth lower electrode.

The segment DY2 corresponds to the first segment, the segment DY3 corresponds to the second segment, the segment DX1 corresponds to the third segment, and the segment DX2 corresponds to the fourth segment.

The sealing layers SE1, SE11, SE12, and SE13 correspond to the first sealing layer, the resin layer RS1 corresponds to the first resin layer, the sealing layer SE2 corresponds to the second sealing layer, and the resin layer RS2 corresponds to the second resin layer.

In each of the pixels PX1, PX2, PX3, and PX4, the subpixel SP1 corresponds to the first subpixel, the subpixel SP2 corresponds to the second subpixel, and the subpixel SP3 corresponds to the third subpixel.

As described above, the present embodiment can provide a display device having a touch sensor function and allowing light or radio waves to pass.

All of the display devices that can be implemented by a person of ordinary skill in the art through arbitrary design changes to the display device described above as the embodiment of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is:

1. A display device, comprising:
a first lower electrode, a second lower electrode, and a third lower electrode that are arranged in order in a first direction in a display area for displaying an image;
organic layers respectively provided on the first lower electrode, the second lower electrode, and the third lower electrode and each having a light emitting layer;
an upper electrode provided on the organic layer; and
a detection electrode for detecting contact or approach of an object to the display area, wherein
the detection electrode extends in a second direction intersecting the first direction, includes a first segment between the first lower electrode and the second lower electrode in plan view, and does not include a segment between the second lower electrode and the third lower electrode.

2. The display device of claim 1, wherein
an interval along the first direction between the first lower electrode and the second lower electrode is smaller than an interval along the first direction between the second lower electrode and the third lower electrode.

3. The display device of claim 1, wherein
a width along the first direction of the first segment is smaller than an interval along the first direction between the first lower electrode and the second lower electrode.

4. The display device of claim 1, wherein
the detection electrode further includes a second segment extending in the second direction and adjacent to the first segment in the first direction, and
the second lower electrode and the third lower electrode are located between the first segment and the second segment in plan view.

5. The display device of claim 4, wherein
the detection electrode further includes:
a third segment extending in the first direction; and
a fourth segment extending in the first direction and adjacent to the third segment in the second direction,
each of the third segment and the fourth segment intersects the first segment and the second segment, and
the second lower electrode and the third lower electrode are located between the third segment and the fourth segment in plan view.

6. The display device of claim 5, further comprising:
a fourth lower electrode adjacent to the second lower electrode in the second direction and located between the first lower electrode and the third lower electrode in the first direction, wherein
the detection electrode further includes a branched segment extending in the first direction, connected to the first segment, and located between the second lower electrode and the fourth lower electrode in plan view.

7. The display device of claim 6, wherein
a width along the second direction of the branched segment is greater than an interval along the second direction between the second lower electrode and the fourth lower electrode.

8. The display device of claim 6, wherein
between the first segment and the second segment, each of the third segment and the fourth segment has:
a first portion adjacent to the second lower electrode or the fourth lower electrode in the second direction and having a first width; and
a second portion adjacent to the third lower electrode in the second direction and having a second width greater than the first width.

9. The display device of claim 6, wherein
the branched segment has a first protruding portion protruding toward the second lower electrode and a second protruding portion protruding toward the fourth lower electrode.

10. The display device of claim 1, further comprising:
a first sealing layer formed of an inorganic insulating material and covering the upper electrode;
a first resin layer provided on the first sealing layer;
a second sealing layer formed of an inorganic insulating material and provided on the first resin layer; and
a second resin layer provided on the second sealing layer, wherein
the detection electrode is provided on the second sealing layer and is covered with the second resin layer.

11. The display device of claim 1, further comprising:
a partition that includes a lower portion having conductivity and contacting the upper electrode and an upper portion protruding relative to side surfaces of the lower portion and surrounds each of the first lower electrode, the second lower electrode, and the third lower electrode, wherein
the first segment overlaps the partition in plan view.

12. The display device of claim 11, wherein
the partition has a slit that does not overlap the detection electrode in plan view.

13. The display device of claim 12, wherein
the slit extends in the second direction between the second lower electrode and the third lower electrode, and
a width along the first direction of the slit is smaller than an interval along the first direction between the second lower electrode and the third lower electrode.

14. The display device of claim 13, further comprising:
a fourth lower electrode adjacent to the second lower electrode in the second direction and located between the first lower electrode and the third lower electrode in the first direction, wherein
the slit further extends between the third lower electrode and the fourth lower electrode.

15. The display device of claim 14, wherein
the detection electrode further includes:
a second segment extending in the second direction and adjacent to the first segment in the first direction;
a third segment extending in the first direction; and
a fourth segment extending in the first direction and adjacent to the third segment in the second direction,
each of the third segment and the fourth segment intersects the first segment and the second segment, and
the slit does not overlap any of the second segment, the third segment, and the fourth segment in plan view.

16. The display device of claim 12, further comprising:
a first sealing layer formed of an inorganic insulating material, covering the upper electrode, and contacting the partition;
a first resin layer provided on the first sealing layer, filling the slit, and contacting the partition;
a second sealing layer formed of an inorganic insulating material and provided on the first resin layer; and
a second resin layer provided on the second sealing layer, wherein
the detection electrode is provided on the second sealing layer and is covered with the second resin layer.

17. A display device, comprising:
a plurality of pixels provided on a display area for displaying an image; and
a detection electrode for detecting contact or approach of an object to the display area, wherein
each of the plurality of pixels includes a first subpixel and a second subpixel adjacent to the first subpixel, and
the detection electrode includes a plurality of segments each surrounding the plurality of pixels in plan view and does not include a segment between the first subpixel and the second subpixel.

18. The display device of claim 17, wherein
each of the plurality of pixels further includes a third subpixel,
the first subpixel and the second subpixel are arranged in a first direction,
the first subpixel and the third subpixel are arranged in the first direction,
the second subpixel and the third subpixel are arranged in a second direction intersecting the first direction, and
the detection electrode includes a branched segment located between the second subpixel and the third subpixel and extending in the first direction in plan view.
